(19) United States
(12) Patent Application Publication
(10) Pub. No.: US 2019/0237446 A1
(43) Pub. Date: Aug. 1, 2019

(54) MICRO-LED 3D DISPLAY MODULES AND METHODS FOR FABRICATING THE SAME

(71) Applicant: LUMENS CO., LTD., Yongin-si (KR)

(72) Inventor: JEONGHO BANG, Yongin-si (KR)

(73) Assignee: LUMENS CO., LTD., Yongin-si (KR)

(21) Appl. No.: 16/249,957

(22) Filed: Jan. 17, 2019

(30) Foreign Application Priority Data
Jan. 31, 2018 (KR) 10-2018-0011732

(51) Int. Cl. H01L 25/13; G02B 5/30

(52) U.S. Cl. CPC H01L 25/13; H01L 2933/0033; G02B 5/3025

(57) ABSTRACT

Micro-LED 3D display modules are disclosed. Each of the micro-LED 3D display module includes a module substrate and a micro-LED array mounted on the module substrate. The micro-LED array includes first micro-LED pixels attached with a first polarization film having a first phase retardation property and second micro-LED pixels attached with a second polarization film having a second phase retardation property.

### BACKGROUND OF THE INVENTION

### 1. Field of the Invention

The present invention relates to micro-LED 3D display modules and methods for fabricating the micro-LED 3D display modules. More specifically, the present invention relates to micro-LED 3D display modules that can be used to manufacture 3D display devices requiring 3D glasses for viewing in which pixels consist of micro-LEDs and polarization films are attached to the pixels, and methods for fabricating the micro-LED 3D display modules.

### 2. Description of the Related Art

Display devices using light emitting diodes (LEDs) as backlight sources have been proposed. Particularly, full-color LED display devices have been proposed in which LEDs emitting light of different wavelengths are grouped to form pixels and the pixels are arrayed in a matrix. Furthermore, micro-LED displays for high-resolution full-color LED display devices have been proposed in which micro-LED chips constitute pixels and the length of one side of each chip is not more than 100 micrometers. In the micro-LED displays, each pixel consists of a group of micro-LEDs emitting light of different wavelengths.

3D displays allow viewers to see stereoscopic images with or without 3D viewing glasses. Thus, 3D displays are divided into glasses and non-glasses types depending on whether viewers need to wear 3D glasses. Particularly, the glasses-type 3D display uses polarization panels or polarization films, which are usually used in current 3D TVs, to separate images. That is, the glasses-type 3D display requires wearing of 3D glasses attached with polarization panels to distinguish two separate images for the left and right eyes. The 3D glasses attached with polarization panels appropriately separate two images from the display and transmit the separate images to the left and right eyes.

The display outputs two separate images corresponding to 3D glasses attached with polarization panels by two methods: spatial and temporal methods.

The spatial method typically uses a film-type patterned retarder (FPR) to transmit two images simultaneously. The temporal approach typically uses shutter glasses (SG) to transmit two different frames alternately. Both methods share the use of polarization panels in common to separate images.

FIG. 1 is a diagram illustrating the principle of FPR type polarization. According to this principle, an image is spatially segmented and transmitted to the human eyes simultaneously. An FPR film including a linear polarization panel (X-LP) and quarter wave films QW1 and QW2 attached onto the linear polarization panel and having phases opposite to each other is used to divide the image into left and right images at column lines on the screen and transmits the divided images. The divided images pass through the films having phases opposite to each other and are distinguished in 3D glasses in front of the eyes such that the right image enters the right eye and the left image enters the left eye.

For example, unpolarized light (light twisted by a liquid crystal material for an LCD or light after emission for an OLED) is linearly polarized to 90° after passing through the linear polarization panel, the right image is linearly polarized to 135° after passing through the 45° quarter wave film QW1, and the left image is linearly polarized to 45° after passing through the −45° quarter wave film QW2. The 135° linearly-polarized right image is linearly polarized to 180° and the 45° linearly-polarized left image is linearly polarized to 90° after passing through a 45° quarter wave film QW1 attached to the right lens of the 3D glasses. The 180° linearly-polarized right image enters the right eye after passing through the downstream 180° linear polarization panel Y-LP but the left image is completely blocked by the 180° linear polarization panel Y-LP.

The shutter glass 3D display repeatedly displays images corresponding to the left and right eyes alternately. 3D glasses play a key role in the shutter glass 3D display. Left and right images are flickeringly displayed from the display and received by 3D glasses that are flickering at left and right sides in response to the flickering images. This is made possible due to the presence of a liquid crystal in the 3D glasses. In the 3D glasses as well as the shutter glass 3D display, the liquid crystal and the polarization panels are used to block/transmit images. However, the presence of the liquid crystal and the accommodation of a battery to electrically control the liquid crystal make the 3D glasses heavy. The flickering disadvantageously causes severe eye strain but the display panel is relatively easy to construct. Particularly, the shutter glass 3D display can avoid problems caused by slow movement of liquid crystal molecules when applied to an OLED, unlike when applied to an LCD.

In addition to the above-described two typical methods, other LCD- and OLED-based 3D display technologies are currently in use. Polarization panels and phase retardation films used in such 3D display technologies are considered applicable to full-color micro-LED displays for micro-LED 3D display devices in which LEDs emitting light of different wavelengths are grouped to form pixels.

### SUMMARY OF THE INVENTION

The present invention has been made in an effort to solve the problems of conventional LCD- and OLED-based display modules, and it is an object of the present invention to provide micro-LED 3D display modules in which micro-LEDs emitting light of different wavelengths are grouped to form pixels, a first polarization film having a first phase retardation property is attached to first micro-LED pixels to pass images through the right lens of 3D glasses and a second polarization film having a second phase retardation property is attached to second micro-LED pixels to pass images through the left lens of the 3D glasses, and the first micro-LED pixels attached with the first polarization film and the second micro-LED pixels attached with the second polarization film are mounted on a module substrate in such a manner that one row of the second micro-LED pixels is located between two rows of the first micro-LED pixels.

A micro-LED 3D display module according to one aspect of the present invention includes a module substrate including a plurality of columns and a micro-LED array mounted on the module substrate wherein the micro-LED array includes first micro-LED pixels attached with a first polarization film having a first phase retardation property and second micro-LED pixels attached with a second polarization film having a second phase retardation property, the first micro-LED pixels are arranged in the row direction in (2N-1) columns (where N is a natural number) of the module substrate, and the second micro-LED pixels are arranged in the row direction in (2N) columns of the module substrate.

According to one embodiment, the first polarization film has a +45° phase retardation and the second polarization film has a −45° phase retardation.

According to one embodiment, the first polarization film includes pieces thereof and each of the pieces is attached to the upper surface of the corresponding first micro-LED pixel.

According to one embodiment, the second polarization film includes pieces thereof and each of the pieces is attached to the upper surface of the corresponding second micro-LED pixel.

A micro-LED 3D display module according to a further aspect of the present invention includes a module substrate and a micro-LED array mounted on the module substrate wherein the micro-LED array includes first micro-LED pixels attached with a first polarization film having a first phase retardation property and second micro-LED pixels attached with a second polarization film having a second phase retardation property.

According to one embodiment, the first LED pixels are arranged in a plurality of rows and the second LED pixels are arranged in a plurality of rows in such a manner that one row of the second micro-LED pixels is arranged between the two adjacent rows of the first micro-LED pixels.

According to one embodiment, the first polarization film has a +45° phase retardation and the second polarization film has a −45° phase retardation.

According to one embodiment, the first polarization film includes an X-axis linear polarization panel having an X-axis linear polarization property and a phase retardation film located outside the X-axis linear polarization panel and having a +45° phase retardation.

According to one embodiment, the second polarization film includes an X-axis linear polarization panel having an X-axis linear polarization property and a phase retardation film located outside the X-axis linear polarization panel and having a −45° phase retardation.

According to one embodiment, the first polarization film is attached to the first micro-LED pixels in rows.

According to one embodiment, the second polarization film is attached to the second micro-LED pixels in rows.

According to one embodiment, each of the first micro-LED pixels and the second micro-LED pixels includes three sub-pixels consisting of a red micro-LED, a green micro-LED, and a blue micro-LED.

A method for fabricating a micro-LED 3D display module according to another aspect of the present invention includes (a) attaching first micro-LED pixels to a first polarization film having a first phase retardation property and attaching second micro-LED pixels to a second polarization film having a second phase retardation property, (b) cutting the first polarization film into pieces such that each of the pieces of the first polarization film is attached to the corresponding first micro-LED pixel and cutting the second polarization film into pieces such that each of the pieces of the second polarization film is attached to the corresponding second micro-LED pixel, (c) reeling the first micro-LED pixels attached with the pieces of the first polarization film and the second micro-LED pixels attached with the pieces of the second polarization film, and (d) mounting the reeled first micro-LED pixels and the reeled second micro-LED pixels on a module substrate.

According to one embodiment, the first polarization film has a +45° phase retardation and the second polarization film has a +45° phase retardation.

According to one embodiment, the reeled first micro-LED pixels are mounted in the row direction and the reeled second micro-LED pixels are mounted so as to be positioned between the adjacent rows of the first micro-LED pixels.

According to one embodiment, the first polarization film includes an X-axis linear polarization panel having an X-axis linear polarization property and a phase retardation film located outside the X-axis linear polarization panel and having a +45° phase retardation; and the second polarization film includes an X-axis linear polarization panel having an X-axis linear polarization property and a phase retardation film located outside the X-axis linear polarization panel and having a −45° phase retardation.

A method for fabricating a micro-LED 3D display module according to yet another aspect of the present invention includes (a) linearly aligning first micro-LED pixels and attaching a first polarization film having a first phase retardation property to the linearly aligned first micro-LED pixels, (b) linearly aligning second micro-LED pixels and attaching a second polarization film having a second phase retardation property to the linearly aligned second micro-LED pixels, (c) attaching the first micro-LED pixels attached with the first polarization film to a module substrate, and (d) attaching the second micro-LED pixels attached with the second polarization film to the module substrate such that the second micro-LED pixels are located between the first micro-LED pixels.

According to one embodiment, the first polarization film has a +45° phase retardation and the second polarization film has a −45° phase retardation.

According to one embodiment, the first micro-LED pixels are linearly aligned using a straight bracket in step (a) and the second micro-LED pixels are linearly aligned using a straight bracket in step (b).

According to one embodiment, the first polarization film includes an X-axis linear polarization panel having an X-axis linear polarization property and a phase retardation film located outside the X-axis linear polarization panel and having a +45° phase retardation; and the second polarization film includes an X-axis linear polarization panel having an X-axis linear polarization property and a phase retardation film located outside the X-axis linear polarization panel and having a −45° phase retardation.

The micro-LED 3D display modules of the present invention are fabricated by attaching a first polarization film having a first phase retardation property to first micro-LED pixels to pass images through the right lens of 3D glasses, attaching a second polarization film having a second phase retardation property to second micro-LED pixels to pass images through the left lens of the 3D glasses, and mounting the first micro-LED pixels attached with the first polarization film and the second micro-LED pixels attached with the second polarization film on a module substrate in such a manner that one row of the second micro-LED pixels is located between two rows of the first micro-LED pixels. The micro-LED 3D display modules of the present invention have a structure in which micro-LEDs emitting light of different wavelengths are grouped to form pixels, unlike conventional LCD- and OLED-based display modules. The micro-LED 3D display modules of the present invention is applicable to the manufacture of 3D display devices.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a diagram illustrating the principle of how a 3D image is represented in a conventional FPR LCD or OLED display;

FIG. 2 is a plan view of a micro-LED 3D display module according to one embodiment of the present invention;

FIG. 3 is a schematic cross-sectional view illustrating one LED pixel of the micro-LED 3D display module of FIG. 2;

FIG. 4 is a flow diagram illustrating the steps of a method for fabricating a micro-LED 3D display module according to one embodiment of the present invention; and

FIG. 5 is a flow diagram illustrating a method for fabricating a micro-LED 3D display module according to a further embodiment of the present invention.

### DETAILED DESCRIPTION OF THE INVENTION

Preferred embodiments of the present invention will now be described with reference to the accompanying drawings. It should be noted that the drawings and embodiments are simplified and illustrated such that those skilled in the art can readily understand the present invention.

FIG. 2 is a plan view of a micro-LED 3D display module 100 according to one embodiment of the present invention.

Referring to FIG. 2, the micro-LED 3D display module 100 includes a micro-LED array 120 and a module substrate 110 mounted with the micro-LED array 120. The micro-LED array 120 includes first micro-LED pixels attached with a first polarization film having a first phase retardation property and second micro-LED pixels attached with a second polarization film having a second phase retardation property. The first micro-LED pixels are arrayed in rows (i.e. in the X-axis direction) denoted by d1 and the second micro-LED pixels are arrayed in rows denoted by d2. Thus, the first micro-LED pixels and the second micro-LED pixels are arrayed in a matrix with rows and columns in the micro-LED array 120. The plurality of rows of the first micro-LED pixels and the plurality of rows of the second micro-LED pixels are arranged in such a manner that one row d2 of the second micro-LED pixels d2 is located between the two adjacent rows d1 and d1 of the first micro-LED pixels.

In another aspect, a micro-LED 3D display module includes a module substrate 110 including a plurality of columns and a micro-LED array 120 mounted on the module substrate 110 wherein the micro-LED array 120 includes first micro-LED pixels attached with a first polarization film having a first phase retardation property and second micro-LED pixels attached with a second polarization film having a second phase retardation property, the first micro-LED pixels are arranged in the row direction in (2N-1) columns (where N is a natural number) of the module substrate, and the second micro-LED pixels are arranged in the row direction in (2N) columns of the module substrate. The first micro-LED pixels are arrayed in rows denoted by d1 and the second micro-LED pixels are arrayed in rows denoted by d2. The plurality of columns of the module substrate 110 are imaginary columns considering a state in which the micro-LED array 120 is mounted on the module substrate 110.

The first polarization film may have a +45° phase retardation and the second polarization film may have a −45° phase retardation.

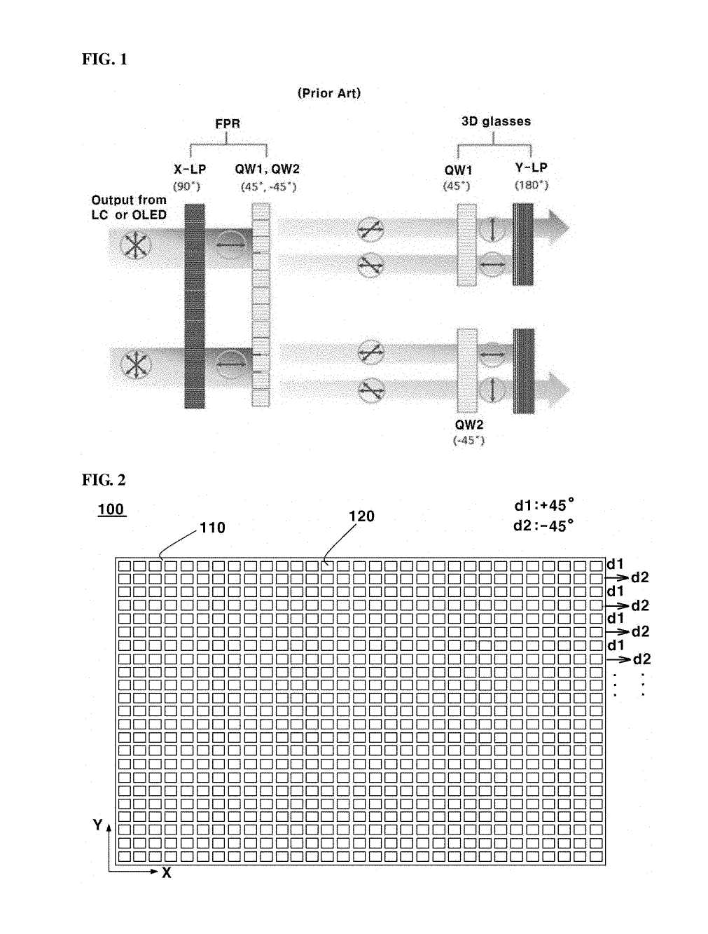

Specifically, the first polarization film may include an X-axis linear polarization panel having an X-axis linear polarization property (90°) and a phase retardation film located outside the X-axis linear polarization panel and having a +45° phase retardation. Referring again to FIG. 1, unpolarized light is linearly polarized to 90° after passing through the linear polarization panel, the right image is linearly polarized to 135° after passing through the 45° quarter wave film, and the left image is linearly polarized to 45° after passing through the −45° quarter wave film QW2. The 135° linearly-polarized right image is linearly polarized to 180° and the 45° linearly-polarized left image is linearly polarized to 90° after passing through a 45° quarter wave film QW1 attached to the right lens of the 3D glasses. The 180° linearly-polarized right image enters the right eye after passing through the downstream 180° linear polarization panel Y-LP but the left image is completely blocked by the 180° linear polarization panel Y-LP.

The first polarization film may be attached to the upper surfaces of the first micro-LED pixels. The second polarization film includes an X-axis linear polarization panel having an X-axis linear polarization property (90°) and a phase retardation film having a −45° phase retardation. The second polarization film may be attached to the upper surfaces of the second micro-LED pixels. Each of the first micro-LED pixels and the second micro-LED pixels may include three micro-LEDs emitting light of different wavelengths.

For example, each of the first micro-LED pixels and the second micro-LED pixels may include a red micro-LED, a green micro-LED, and a blue micro-LED as sub-pixels. The upper surfaces of the micro-LED pixels refer to the light-emitting surfaces of the micro-LEDs in the micro-LED pixels. In each of the first polarization film and the second polarization film, the phase retardation film is attached to the outer side of the X-ray linear polarization panel (see the arrangement in FIG. 1).

The first polarization film is attached to the upper surface of each of the first micro-LED pixels. For example, the first polarization film may be cut into pieces and each of the pieces of the first polarization film may be attached to the upper surface of the corresponding first micro-LED pixel. Likewise, pieces of the second polarization film may be attached to the upper surfaces of the corresponding second micro-LED pixels.

Alternatively, the first polarization film may be attached to the first micro-LED pixels in rows and the second polarization film may be attached to the second micro-LED pixels in rows.

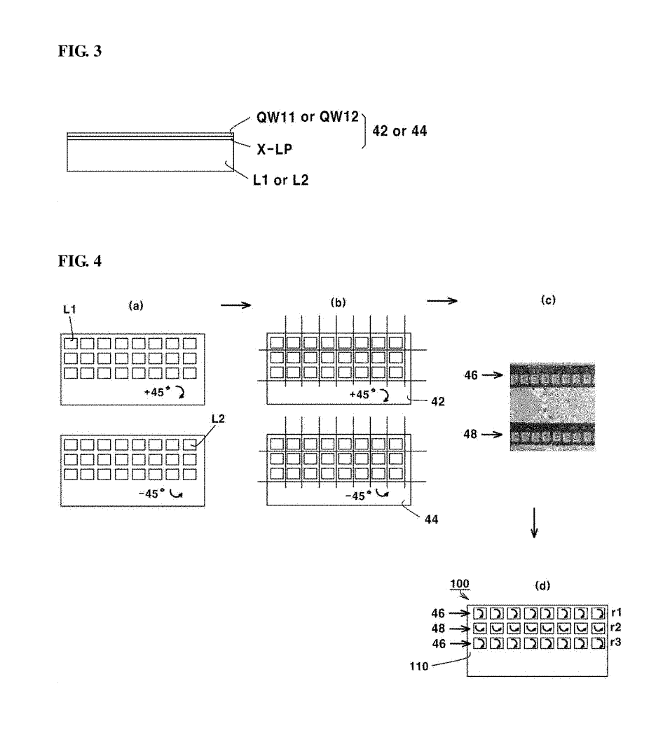

FIG. 3 illustrates attachment of the polarization film 42 or 44 to the upper surface of one L1 or L2 of the micro-LED pixels. The polarization film includes an X-axis linear polarization panel X-LP and a phase retardation film QW11 or QW12. The first polarization film 42 attached to the upper surface of the first micro-LED pixel L1 may include an X-axis linear polarization panel X-LP and a phase retardation film QW11. The second polarization film 44 attached to the upper surface of the second micro-LED pixel L2 may include an X-axis linear polarization panel X-LP and a phase retardation film QW12.

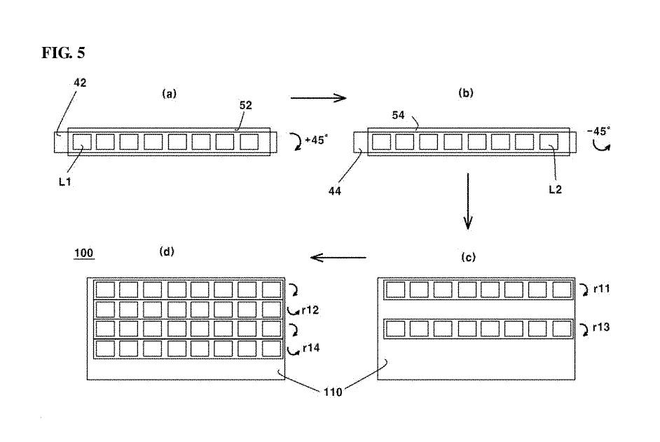

FIG. 4 is a flow diagram illustrating the steps of a method for fabricating a micro-LED 3D display module according to one embodiment of the present invention in which pieces of polarization films are attached to the upper surfaces of corresponding micro-LED pixels.

Referring to FIG. 4, the method includes (a) attaching first micro-LED pixels L1 to a first polarization film 42 having a first phase retardation property and attaching second micro-LED pixels L2 to a second polarization film 44 having a second phase retardation property, (b) cutting the first polarization film 42 into pieces such that each of the pieces of the first polarization film 42 is attached to the corresponding first micro-LED pixel L1 and cutting the second polarization film 44 into pieces such that each of the pieces of the second polarization film 44 is attached to the corresponding second micro-LED pixel L2, (c) reeling the first micro-LED pixels L1 attached with the pieces of the first polarization film 42 and the second micro-LED pixels L2 attached with the pieces of the second polarization film 44, and (d) mounting the reeled first micro-LED pixels 46 and the reeled second micro-LED pixels 48 on a module substrate 110.

The first polarization film 42 may have a +45° phase retardation and the second polarization film 44 may have a −45° phase retardation. More specifically, the first polarization film 42 may include an X-axis linear polarization panel X-LP (see FIG. 3) having an X-axis linear polarization property and a phase retardation film QW11 located outside the X-axis linear polarization panel X-LP and having a +45° phase retardation; and the second polarization film 44 includes an X-axis linear polarization panel X-LP having an X-axis linear polarization property and a phase retardation film QW12 located outside the X-axis linear polarization panel X-LP and having a −45° phase retardation.

In step (d), the reeled first micro-LED pixels 46 are mounted in rows r1 and r3 and the reeled second micro-LED pixels 48 are mounted on the module substrate 110 so as to be positioned between the adjacent rows r1 and r3 of the first micro-LED pixels. Each of the first micro-LED pixels L1 and the second micro-LED pixels L2 may include three sub-pixels consisting of a red micro-LED, a green micro-LED, and a blue micro-LED.

FIG. 5 is a flow diagram illustrating a method for fabricating a micro-LED 3D display module according to a further embodiment of the present invention in which polarization films are attached to micro-LED pixels in rows.

Referring to FIG. 5, the method includes (a) linearly aligning first micro-LED pixels L1 and attaching a first polarization film 42 having a first phase retardation property to the linearly aligned first micro-LED pixels L1, (b) linearly aligning second micro-LED pixels L2 and attaching a second polarization film 44 having a second phase retardation property to the linearly aligned second micro-LED pixels L2, (c) attaching the first micro-LED pixels L1 attached with the first polarization film 42 to a module substrate 110, and (d) attaching the second micro-LED pixels L2 attached with the second polarization film 44 to the module substrate 110 such that the second micro-LED pixels L2 are located between the first micro-LED pixels L1.

Here, the first polarization film 42 may have a +45° phase retardation and the second polarization film 44 may have a −45° phase retardation. More specifically, the first polarization film 42 may include an X-axis linear polarization panel X-LP (see FIG. 3) having an X-axis linear polarization property and a phase retardation film QW11 located outside the X-axis linear polarization panel X-LP and having a +45° phase retardation; and the second polarization film 44 includes an X-axis linear polarization panel X-LP having an X-axis linear polarization property and a phase retardation film QW12 located outside the X-axis linear polarization panel X-LP and having a −45° phase retardation. Each of the first micro-LED pixels L1 and the second micro-LED pixels L2 may include three sub-pixels consisting of a red micro-LED, a green micro-LED, and a blue micro-LED.

The first micro-LED pixels L1 are linearly aligned using a straight bracket 52 in step (a) and the second micro-LED pixels L2 are linearly aligned using a straight bracket 54 in step (b).

Although the micro-LED 3D display modules and the methods according to the foregoing embodiments of the present invention are limited to FPR 3D displays requiring 3D glasses, they can be applied to the manufacture of other micro-LED 3D display devices using micro-LED-based 3D display modules in which micro-LEDs are grouped to form pixels.

What is claimed is:

1. A micro-LED 3D display module comprising a module substrate comprising a plurality of columns and a micro-LED array mounted on the module substrate wherein the micro-LED array comprises first micro-LED pixels attached with a first polarization film having a first phase retardation property and second micro-LED pixels attached with a second polarization film having a second phase retardation property, the first micro-LED pixels are arranged in the row direction in (2N-1) columns (where N is a natural number) of the module substrate, and the second micro-LED pixels are arranged in the row direction in (2N) columns of the module substrate.

2. The micro-LED 3D display module according to claim 1, wherein the first polarization film has a +45° phase retardation and the second polarization film has a −45° phase retardation.

3. The micro-LED 3D display module according to claim 1, wherein the first polarization film comprises pieces thereof and each of the pieces is attached to the upper surface of the corresponding first micro-LED pixel.

4. The micro-LED 3D display module according to claim 1, wherein the second polarization film comprises pieces thereof and each of the pieces is attached to the upper surface of the corresponding second micro-LED pixel.

5. A micro-LED 3D display module comprising a module substrate and a micro-LED array mounted on the module substrate wherein the micro-LED array comprises first micro-LED pixels attached with a first polarization film having a first phase retardation property and second micro-LED pixels attached with a second polarization film having a second phase retardation property.

6. The micro-LED 3D display module according to claim 5, wherein the first LED pixels are arranged in a plurality of rows and the second LED pixels are arranged in a plurality of rows in such a manner that one row of the second micro-LED pixels is arranged between the two adjacent rows of the first micro-LED pixels.

7. The micro-LED 3D display module according to claim 5, wherein the first polarization film has a +45° phase retardation and the second polarization film has a −45° phase retardation.

8. The micro-LED 3D display module according to claim 5, wherein the first polarization film comprises an X-axis linear polarization panel having an X-axis linear polarization property and a phase retardation film located outside the X-axis linear polarization panel and having a +45° phase retardation.

9. The micro-LED 3D display module according to claim 5, wherein the second polarization film comprises an X-axis linear polarization panel having an X-axis linear polarization property and a phase retardation film located outside the X-axis linear polarization panel and having a −45° phase retardation.

10. The micro-LED 3D display module according to claim 5, wherein the first polarization film is attached to the first micro-LED pixels in rows.

11. The micro-LED 3D display module according to claim 5, wherein the second polarization film is attached to the second micro-LED pixels in rows.

12. The micro-LED 3D display module according to claim 5, wherein each of the first micro-LED pixels and the second micro-LED pixels comprises three sub-pixels consisting of a red micro-LED, a green micro-LED, and a blue micro-LED.

13. A method for fabricating a micro-LED 3D display module, comprising (a) attaching first micro-LED pixels to a first polarization film having a first phase retardation property and attaching second micro-LED pixels to a second polarization film having a second phase retardation property, (b) cutting the first polarization film into pieces such that each of the pieces of the first polarization film is attached to the corresponding first micro-LED pixel and cutting the second polarization film into pieces such that each of the pieces of the second polarization film is attached to the corresponding second micro-LED pixel, (c) reeling the first micro-LED pixels attached with the pieces of the first polarization film and the second micro-LED pixels attached with the pieces of the second polarization film, and (d) mounting the reeled first micro-LED pixels and the reeled second micro-LED pixels on a module substrate.

14. The method according to claim 13, wherein the first polarization film has a +45° phase retardation and the second polarization film has a +45° phase retardation.

15. The method according to claim 13, wherein the reeled first micro-LED pixels are mounted in the row direction and the reeled second micro-LED pixels are mounted so as to be positioned between the adjacent rows of the first micro-LED pixels.

16. The method according to claim 13, wherein the first polarization film comprises an X-axis linear polarization panel having an X-axis linear polarization property and a phase retardation film located outside the X-axis linear polarization panel and having a +45° phase retardation; and the second polarization film comprises an X-axis linear polarization panel having an X-axis linear polarization property and a phase retardation film located outside the X-axis linear polarization panel and having a −45° phase retardation.

17. A method for fabricating a micro-LED 3D display module, comprising (a) linearly aligning first micro-LED pixels and attaching a first polarization film having a first phase retardation property to the linearly aligned first micro-LED pixels, (b) linearly aligning second micro-LED pixels and attaching a second polarization film having a second phase retardation property to the linearly aligned second micro-LED pixels, (c) attaching the first micro-LED pixels attached with the first polarization film to a module substrate, and (d) attaching the second micro-LED pixels attached with the second polarization film to the module substrate such that the second micro-LED pixels are located between the first micro-LED pixels.

18. The method according to claim 17, wherein the first polarization film has a +45° phase retardation and the second polarization film has a −45° phase retardation.

19. The method according to claim 17, wherein the first micro-LED pixels are linearly aligned using a straight bracket in step (a) and the second micro-LED pixels are linearly aligned using a straight bracket in step (b).

20. The method according to claim 17, wherein the first polarization film comprises an X-axis linear polarization panel having an X-axis linear polarization property and a phase retardation film located outside the X-axis linear polarization panel and having a +45° phase retardation; and the second polarization film comprises an X-axis linear polarization panel having an X-axis linear polarization property and a phase retardation film located outside the X-axis linear polarization panel and having a −45° phase retardation.
